(19) United States
(12) Patent Application Publication
(10) Pub. No.: US 2009/0208737 A1
(43) Pub. Date: Aug. 20, 2009

(54) LAMELLA STRUCTURED THIN FILMS WITH ULTRALOW DIELECTRIC CONSTANTS AND HIGH HARDNESS AND METHOD FOR MANUFACTURING THE SAME

(75) Inventors: Young Uk Kwon, Gyeonggi-do (KR); U. Hwang Lee, Gyeonggi-do (KR); Hyun Ju Lee, Gyeonggi-do (KR); Ki Rim Lee, Gyeonggi-do (KR)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: Sungkyunkwan University Foundation for Corporate Collaboration, Gyeonggi-do (KR)

(21) Appl. No.: 12/352,178

(22) Filed: Jan. 12, 2009

(30) Foreign Application Priority Data
Jan. 18, 2008 (KR) 10-2008-0005595

(51) Int. Cl. B32B 7/02; H01L 21/31

(52) U.S. Cl. 428/336; 428/446; 438/787; 257/E21.24

(57) ABSTRACT

There are provided lamella structured thin films having ultralow dielectric constants and high hardness, and the method for manufacturing the same. In the lamella structured thin film, silica layers and air layers are alternately and repeatedly stacked on the surface of a wafer in the vertical direction. The method of manufacturing the lamella structured thin film includes, agitating silica sol solution containing surfactant and silica precursor, spin-coating the solution on silicon wafer, aging the wafer, and annealing the wafer to remove the surfactant and organic materials from the wafer. The lamella structured thin film has excellent mechanical strength and high chemical stability, and in particular, has significantly low dielectric constant of no more than 2.5 and high hardness. In the method of manufacturing the lamella structured thin film, semiconductor processes can be made simple and economical since only pure silica is used and no additionally surface treatment is performed.

### BACKGROUND OF THE INVENTION

1. Field of the Invention

The present invention relates to lamella structured thin films having ultralow dielectric constants (K) and high hardness and a method of manufacturing the same.

2. Description of the Background Art

Recently, researches on new materials having low dielectric constant are actively performed since the low dielectric constant material is required for reducing the feature dimension of an integrated circuit to improve the degree of integration. The silicon dioxide (SiO₂) film has been the material of choice for the conventional semiconductor packaging and the interlayer insulating material. However, the dielectric constant of the silicon dioxide (SiO₂) film is about 4, which is too high to be used as the next generation chip-to-chip package material that particularly requires low dielectric constant.

On the other hand, several researchers have sought solutions to the problems of silicon dioxide from nanoporous silica, which can have lower dielectric constants by introducing air of dielectric constant 1 into the nanometer-sized pores. The nanoporous silica have been synthesized by spin-on glass (SOG) method or chemical deposition methods by using tetramethoxysilane (TMOS), tetraethoxylsilane (TEOS), or other similar compounds as the precursor. The nanoporous silica have many advantages: Because their pore size can be controlled, their pore density, mechanical strength and dielectric constant can be controlled. They can have low dielectric constant and thermal stability up to 900° C., and their pore dimensions are smaller than the feature dimensions of the microelectronics in the integrated circuits. They can be synthesized by using silica or TEOS that are used in the current semiconductor industry, and by using synthesis methods similar to the conventional SOG process. Therefore, the nanoporous silica thin films have been synthesized by various methods based on the conventional techniques.

However, in order to reduce the dielectric constant, the porosity has to be increased, which significantly reduces the mechanical strength of the silica thin film.

In particular, although the characteristic standards for the material is not established because the kind of the low dielectric constant material used for manufacturing a semiconductor device varies with the wiring line structure and the application field of the semiconductor device, stable electrical, chemical, mechanical, and thermal characteristics are commonly required for the dielectric materials. That is, in order to increase metallization density and to reduce signal delay, the material must have low dielectric constant and allow facile design of metallization and facile processes of manufacturing. In addition, chemical inertness and low ion transport property during the metallization process, and mechanical strength enough to withstand processes such as a chemical mechanical polishing (CMP) process are required. A dielectric material cannot be used as the interlayer material for metallization unless the dielectric material satisfies various characteristics such as low moisture absorption to prevent the mechanical failure or the increase of dielectric constant, heat resistance against the processing temperature, adhesive force capable of minimizing various stresses and lamination that can be generated by the interface between low dielectric material and metal, low stress, and low thermal expansion coefficient.

As described above, the excellent thermal, chemical, and mechanical characteristics including low dielectric constant and high mechanical strength are objects to be simultaneously pursued in the researches on low dielectric constant materials. However, since these objects conflict with each other in the conventional material design, there have been no solutions.

Therefore, the inventors of the present invention conducted researches on manufacturing lamella structured thin film that, while maintaining the characteristics of the conventional silicon dioxide film, has lower dielectric constant than the conventional dielectric materials and excellent electrical, chemical, mechanical, and thermal characteristics simultaneously.

### SUMMARY OF THE INVENTION

It is an object of the present invention to provide lamella structured thin films having ultralow dielectric constants and high hardness.

It is another object of the present invention to provide a method of manufacturing lamella structured thin films having ultralow dielectric constants and high hardness through simple and economical processes.

In order to achieve the above objects, there is provided lamella structured thin film, in which silica layers and air layers are alternately and repeatedly stacked along the vertical direction of the surface of a wafer.

That is, the silica layers having thickness of 0.1 to 10 nm, preferably 1 to 8 nm, and the air layers having thickness of 0.1 to 10 nm, preferably 1 to 5 nm, are stacked on the surface of a wafer with the repeat thickness of 0.2 to 20 nm, preferably 2 to 13 nm, and more preferably 7 to 9 nm in the vertical direction. However, the repeat thickness of the lamella structured thin film is not limited. For example, the thicknesses of the silica layers and the air layers can vary with the change of the composition or the agitation time of the silica sol solution.

Also, there is provided a method of manufacturing lamella structured thin films having ultralow dielectric constant and high hardness, comprising agitating silica sol solution containing surfactant and silica precursor, spin-coating the solution on a silicon wafer to form a thin film, aging the thin film, and heat-treating the thin film to remove the surfactant and organic materials from the thin film.

According to the present invention, lamella structured thin film is formed by a method based on evaporation induced self-assembly (EISA) mechanism in which the precursor solution is evaporated so that the surfactant, the structure directing agent, forms a mesostructure depending on the volume fraction of the surfactant in the spun-cast thin film.

That is, when the size, the distribution, and the amount of silica sol particles and the amount of the surfactant are controlled, a structure in which the silica particles and the surfactant are alternatively repeated, that is, a lamella structure can be obtained. In general, when such lamella structured thin film is heat-treated at high temperature, since the surfactant as an organic material is heated to be removed so that the space occupied by the surfactant is emptied, adjacent silica layers become in contact with each other (that is, the air layers disappear). As a result, a thin film structure that contains no structure in the length scale of a range of nanometers is expected. At this time, according to the present invention, to the contrary, conditions such as the composition of the silica sol solution and treatment after spin-coating or evaporation are controlled so that the space that has been previously occupied by the surfactant is not completely removed but is converted to layers having a significantly lower density than the silica layers, that is, “the air layers”.

Therefore, it is important that the composition of the surfactant is in a specific range. That is, when the composition range of the surfactant deviates from the specific value, thin film having structures other than the lamella structure is formed. Then, the physical properties such as low dielectric constant and high surface strength represented in the lamella structure thin film according to the present invention are not obtained. For example, a cubic structure thin film has a dielectric constant of about 3 to 4 and a hardness value of about 0.3 GPa so that it is not possible to obtain physical property effect of the low dielectric constant and the high hardness represented in the lamella structure thin film. The silica sol solution preferably contains a surfactant of 0.1 to 0.8 wt % and silica of 5 to 20 wt % for the weight of the entire silica sol solution.

All kinds of surfactants used for synthesizing a mesostructured material such as cetyltrimethylammonium bromide (CTAB), block copolymers having chemical formulas of EOₘPOₙEOₘ and EOₘPOₙ (EO is ethylene oxide, PO is propylene oxide, and n and m are integers), block copolymer (in Brij type) having a chemical formula CₘH₂ₘ₊₁EOₙ (EO is an ethylene oxide and n and m are integers), tween series surfactants, triton series surfactants, and tergitol series surfactants can be used as the surfactant. In particular, a block copolymer (F-127 manufactured by Sigma-Aldrich) having chemical formula of EO₁₀₆PO₇₀EO₁₀₆ can be used as the surfactant.

Triethoxysilane (TES), trimethoxysilane (TMOS), or vinyltrimethoxysilane (VTMOS) can be used as the silica precursor. In particular, tetraethoxysilane (TEOS) is preferably used as the silica precursor.

The silica sol solution can further contain solvent and/or catalyst. All kinds of solvents used for synthesizing the mesopstructured materials such as water, butanol, methanol, ethanol, propanol, and other organic solvent can be used as the solvent. Ethanol is preferred as the solvent. Acids such as HNO₃, HCl, HBr, H₁, H₂SO₄, or HClO₄, can be used as the catalyst. In particular, HCl is preferred as the catalyst.

The silica sol solution contains silica of 5 to 20 wt % and surfactant of 0.1 to 0.8 wt %, preferably, silica of 8 to 15 wt % and surfactant of 0.1 to 0.6 wt % for the weight of the entire solution. The silica sol solution can also contain solvent of 70 to 87 wt % and catalyst of 5.04×10⁵ to 1.97×10⁻⁴ wt %.

In a preferred embodiment of the present invention, silica sol solution can contain TEOS as silica precursor, F-127 as surfactant, HCl as acid catalyst, and H₂O and EtOH as solvents and the molar ratio of TEOS:F-127:HCl:H₂O:EtOH is preferably 1:1.65×10⁻³ to 6.60×10⁻³:2.08×10³ to 7.03×10³:2.31 to 4.62:22.6 to 93.90. However, the present invention is not limited to the above.

The agitating process can be performed for 10 to 60 hours, preferably, 10 to 30 hours. At this time, since the lamella structured thin film is not formed with the agitation temperature about 10° C., the silica sol solution is preferably agitated at the temperature about 20 to 30° C. The humidity during the agitating process is preferably 18 to 40%.

The aging process is preferably performed at a temperature of 50 to 100° C. for 12 to 24 hours.

The thin film generated according to the present invention has lamella structure in which the air layers and the silica layers are alternately arranged on the surface of the wafer in the vertical direction. Actually, the thin film has a structure in which the density of silica is periodically increased and reduced in the vertical direction to the surface of the wafer. The density variation between the two kinds of layers can be abrupt and/or continuous. In other words, the boundary between the silica layer and the air layer is not clearly limited.

Therefore, in the specification and claims “the silica layers” mean portions having high silica density of 50 wt % or more, preferably, 70 wt % or more, and more preferably, 90 wt % or more, and “the air layers” mean portions having low silica density and relatively high air ratio in the repeated structures, that is, layers composed of silica of 50 wt % or less, preferably, 30 wt % or less.

In the spin-coating process, the silica sol solution is dropped on the center of the wafer while rotating the wafer by a predetermined rpm. The dropped solution is coated on the surface of the wafer while uniformly spreading to the periphery by centrifugal force. According to the present invention, the spin-coating process is preferably performed at a temperature of 25 to 35° C. and with a humidity of 55 to 80%.

The lamella structured thin film according to the present invention has the following effects.

First, the high hardness of the films can be understood in an analogy to the superhard coating having similar structure characteristics. The superhard coating or superhard thin film is a multilayered structure in which a material having significantly high hardness and a material having relatively low hardness are alternately stacked to thicknesses of several nm, respectively, by a vapor deposition technique. That is, the material having significantly high hardness and the material having relatively low hardness are alternately stacked in a repeat thickness of about 10 nm. In such lamella structured thin film, resistance against external mechanical shock is significantly larger than the average of the two materials. In the film made of only the material having high hardness, the external shock is effectively transmitted to the inside of the material. However, in the lamella structured thin film, since the external shock spreads at the interface between the material with high hardness and the material with low hardness, it is possible to prevent the external shock from being transmitted to the inside of the thin film. Since the thin film according to the present invention has the structure in which silica having relatively high hardness and the air layer having significantly low hardness are alternately stacked, it has the effect of dissipating the external shock. Therefore, although the thin film of the present invention is made of silica having low hardness, its hardness is higher than pure silica.

In addition, the lamella structured thin film in which silica having relatively high dielectric constant and air having lower dielectric constant are repeated in the range of several nm provides a mechanism that effectively reduces the dielectric constant. The mechanism can be explained by the changes in the overall dielectric constant when two dielectric materials having different dielectric constants are differently arranged. The two dielectric materials can be connected to each other in parallel or in serial as illustrated in FIG. 12.

Referring to FIG. 12, when two dielectric materials are connected to each other in parallel, the total capacity is the sum of the capacities of the two dielectric materials. Therefore, the overall dielectric constant is the average of the dielectric constants of the two dielectric materials. That is, the overall dielectric constant linearly changes in accordance with the variation of the relative ratios of the two dielectric materials. On the other hand, when the two dielectric materials are serially connected to each other, the inverse of the overall dielectric constant is the sum of the inverses of the dielectric constants of the two dielectric materials. Therefore, for the case when the amounts of silica and air that constitute the thin film are equal to each other, the overall dielectric constant is lower when they are connected to each other in serial than in parallel. In the lamella structured thin film according to the present invention, when the silica layers and the air layers are regarded as different kinds of dielectric materials, it can be considered that the dielectric materials are serially connected to each other. To the contrary, all of the conventional silica thin film dielectric materials correspond to the connection in parallel.

In the conventional silica thin film, in order to reduce the dielectric constant, the ratio of pores is to be increased, which deteriorates the mechanical strength of the thin film. On the other hand, according to the present invention, since it is possible to reduce the dielectric constant lower than that of the conventional silica thin film while reducing the ratio of the pores, the mechanical strength of the thin film does not significantly deteriorate. Also, since the lamella structured thin film itself represents the effect of increasing the hardness, the hardness of the film increases.

Therefore, it is possible to provide thin films having ultralow dielectric constants and high mechanical strength simultaneously, which the prior arts could not achieve. Therefore, the present invention provides structure that can solve the two problems and a method of manufacturing actually usable materials.

In the conventional porous low dielectric constant thin films, the pores are connected to the outside of the thin film so that moisture can easily permeate to the internal pores. The moisture increases the dielectric constant. The pores of the lamella structured thin film according to the present invention with the air layer between the dense silica layers is prevented from being connected to the outside, and accordingly moisture does not permeate. Therefore, it is possible to prevent the dielectric constant from being rapidly increased by absorbing moisture.

In summary, the lamella structured thin film manufactured by the present invention is made of silica material and has excellent mechanical strength, chemical stability, and low dielectric constant (K is preferably no more than 2.5, and more preferably, no more than 2.0).

In addition, in the method of manufacturing the lamella structured thin film, since only pure silica is used and no additional surface treatment is required, the semiconductor fabrication processes can be simple and economical.

### BRIEF DESCRIPTION OF THE DRAWINGS

FIG. 1 is the flowchart illustrating the method of manufacturing lamella structured thin film having ultralow dielectric constants and high hardness according to the present invention;

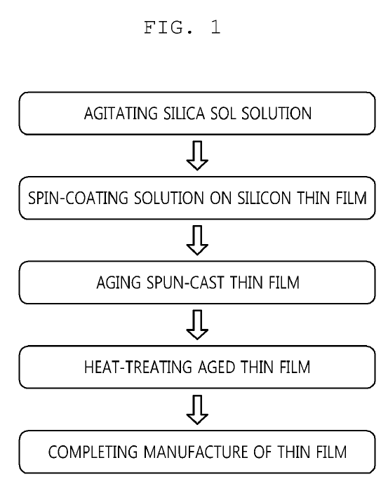

FIG. 2 illustrates the results of X-ray diffraction (XRD) analyzing the lamella structured thin film according to the present invention;

FIG. 3 illustrates the results of XRD analyzing the lamella structured thin film according to the present invention that additionally underwent high temperature treatment;

FIG. 4 illustrates the results of infrared (IR) spectroscopy analyzing the lamella structured thin film according to the present invention;

FIG. 5 illustrates transmission electron microscope (TEM) images for observing the lamella structured thin film according to the present invention;

FIG. 6 illustrates high resolution TEM images for observing the air layers and the silica layers of the lamella structured thin film according to the present invention;

FIG. 7 illustrates scanning electron microscope (SEM) images for observing the thicknesses of the lamella structured thin film according to the present invention;

FIG. 8 illustrates the results of analyzing the nanoindentation measurements of the lamella structured thin film according to the present invention;

FIG. 9 illustrates the results of analyzing electric capacities Cp for obtaining the dielectric constants of the lamella structured thin film according to the present invention;

FIG. 10 illustrates the results of analyzing the IR spectrums of the lamella structured thin film according to the present invention for observing the effect of water vapor of boiling water to the thin films;

FIG. 11 illustrates the results of analyzing the nuclear magnetic resonance (NMR) spectrums of the precursor silica sol solutions of the lamella structured thin film according to the present invention; and

FIG. 12 exemplarily illustrates two methods of connecting two dielectric materials to each other.

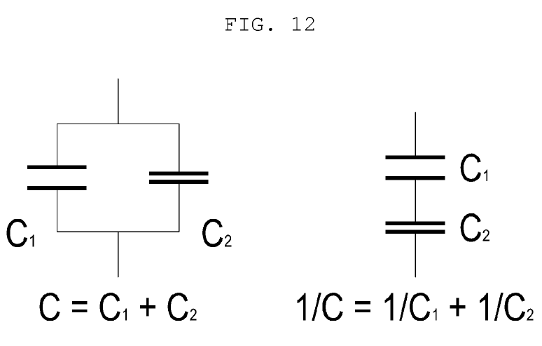

### DETAILED DESCRIPTION OF PREFERRED EMBODIMENTS

The present invention now will be described more fully with reference to embodiments thereof. However, it will be understood by those skilled in the art that various changes in form and details may be made therein without departing from the spirit and scope of the invention as defined by the appended claims.

Manufacture of Lamella Structured Thin Film

The amount of tetraethoxy silane (TEOS) of 99.999% manufactured by Sigma-Aldrich as the material of silica wall was fixed to 1.0 g and the amounts of surfactant F-127 manufactured by Sigma-Aldrich, solvent EtOH, and catalyst HCl as structure forming materials were controlled as illustrated in TABLE 1 to provide solutions for four lamella structured thin films. In TABLE 1, numbers represent molar ratio for one mole of TEOS.

TABLE 1

| | Composition | | | | | |
|---|---|---|---|---|---|---|
| | Agitation | | | | | |
| Film | time | TEOS | F-127 | HC1 | H₂O | EtOH |
| SKUL- | 12 | 1 | 6.60 × 10⁻³ | 3.33 × 10⁻³ | 2.31 | 45.3 |
| 1 | | | | | | |
| SKUL- | 12 | 1 | 4.95 × 10⁻³ | 3.33 × 10⁻³ | 2.31 | 22.6 |
| 2 | | | | | | |
| SKUL- | 24 | 1 | 1.65 × 10⁻³ | 3.33 × 10⁻³ | 2.31 | 22.6 |
| 3 | | | | | | |
| SKUL- | 24 | 1 | 1.65 × 10⁻³ | 7.03 × 10⁻³ | 2.31 | 22.6 |
| 4 | | | | | | |

The solutions were agitated under conditions defined as temperature of 15° C. and humidity of no more than 11% at the agitation times illustrated in TABLE 1. Then the solutions were spin-coated on a silicon wafer having the size of 1×1 cm under conditions of the temperature of 28 to 29° C. and the humidity of 60% at the speed of 4,500 rpm for 1 minute. At this time, the silicon wafer was dipped into Piranha (a 1:1 mixture of H₂SO₄:H₂O₂) for about 2 hours and then, was washed by distilled water and ethanol so that OH groups were formed on the surface of silicon wafer. Then, the spun-cast thin film on the silicon wafer was aged in an oven at a temperature of 80° C. for 12 to 24 hours. Then, the thin film was put in a furnace and, after the temperature of the furnace was increased to 450° C. at the speed of 1° C./min, was kept at 450° C. for 5 hours. Then, the temperature of the furnace was reduced to 40° C. at a speed of 10° C./min. Then, the surfactant and the organic materials were removed to manufacture porous thin films.

X-Ray Diffraction (XRD) Analysis

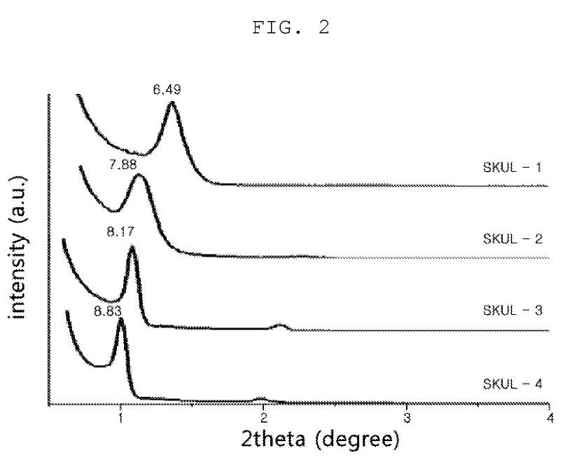

As illustrated in FIG. 2, X-ray diffraction (XRD) analysis was performed using D/MAX-2200 Ultima (manufactured by Rigaku). The wavelength of a light source was CuK α of 1.5406 Å and the repeat thickness (d value) was calculated by the Bragg's law (2d sin θ=nλ).

X-Ray Diffraction (XRD) Analysis after High Temperature Treatment

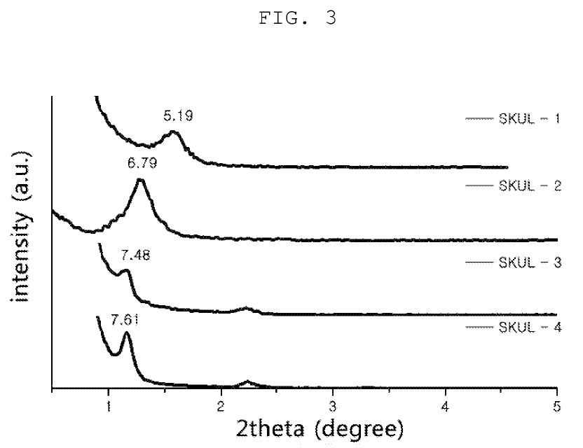

The thin films obtained by performing the heat-treatment process at 450° C. for 5 hours were high temperature heat treated at 800° C. for 30 minutes and taken to X-ray diffraction (XRD) analysis (refer to FIG. 3). As a result, it was noticed that the lamella structured thin film were maintained even at a high temperature. When the result of performing high temperature heat treatment on the thin films at 800° C. was compared with the result of heat treating the thin films at 450° C., it was noticed that the d value was reduced, since the magnitude of the contraction of the air layer at 800° C. is larger than at 450° C., although the lamella structured thin films were maintained by the high temperature treatment, Therefore, it was noticed that the lattice distance could be controlled by the high temperature heat treatment.

Infrared (IR) Analysis

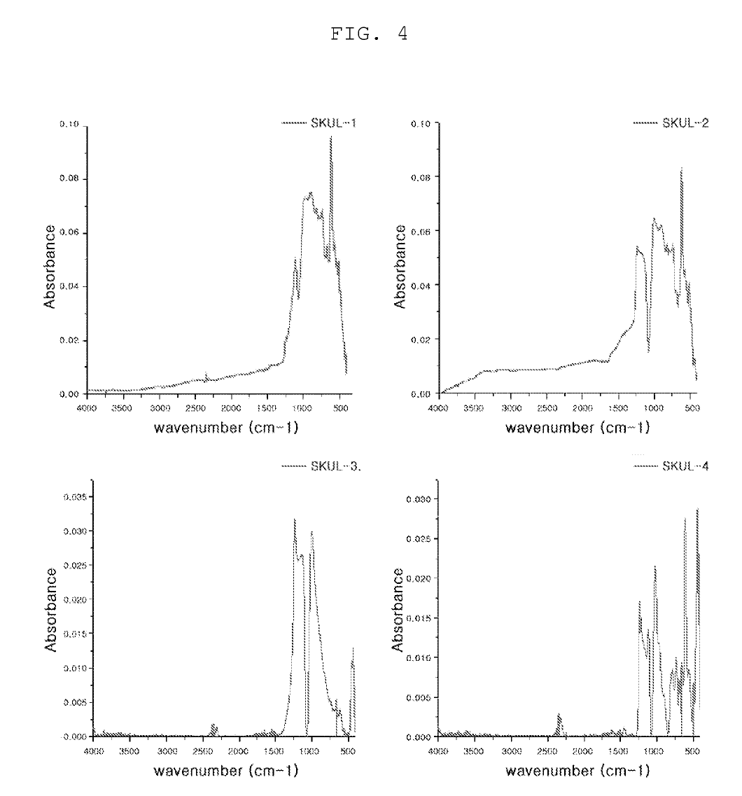

The thin films obtained by the embodiment 1 were IR analyzed using TENSOR27 (manufactured by BRUKER) (refer to FIG. 4). When the lamella structured thin film contain H₂O, since the dielectric constant of H₂O is high (˜80), the dielectric constant increases. Therefore, in order to be applied as low dielectric constant material, the thin films are required to have low or no moisture absorption. The H₂O peak appears in the range from 3,400 to 3,600 cm⁻¹ in IR. The H₂O peak was not shown in the lamella structured thin film according to the present invention. Therefore, since the lamella structured thin films of the present invention have low moisture absorbing property and do not contain water, it was noticed that the dielectric constants of the lamella structured thin films according to the present invention were relatively low (TABLE 2).

Transmission Electron Microscope (TEM) Analysis

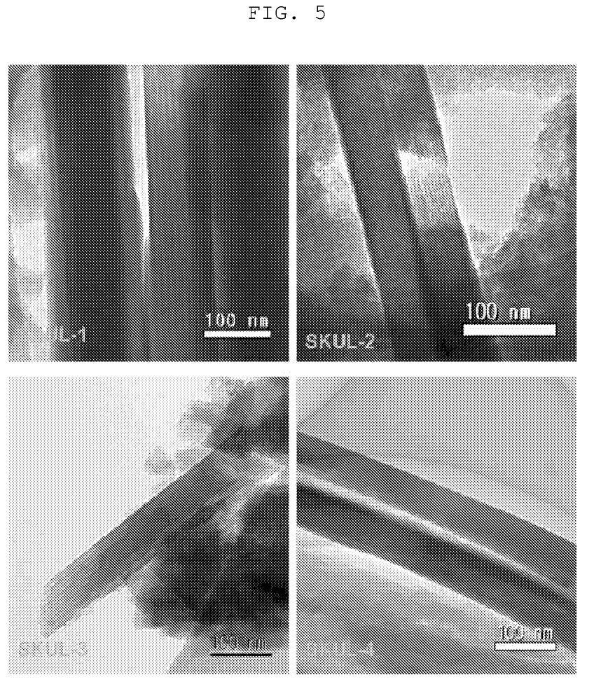

FIG. 5 illustrates the results obtained by a high-resolution transmission electron microscope (HRTEM; JSM-3011, 300 kV) and a high voltage electron microscope (HVEM; JEM-ARM 1300S, 125 kV). It was revealed that the lamella structured thin films of the present invention had a lamella structure consisting of silica layers and air layers.

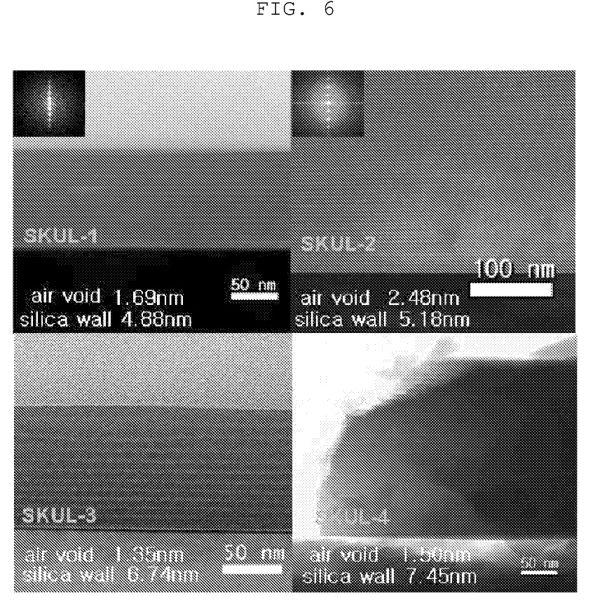

The TEM photographs of FIG. 6 illustrate that the sum of the thicknesses of the silica layer and the air layer of the lamella structured thin films of the present invention coincide with the repeat thickness (d values) obtained by X-ray diffraction (XRD) (TABLE 2).

TABLE 2
Thicknesses of air layers and silica layers

| | Thickness of | Thickness of | Repeat |
|---|---|---|---|
| Thin film | air layer | silica layer | thickness |
| SKUL-1 | 1.7 nm | 4.8 nm | 6.5 nm |
| SKUL-2 | 2.5 nm | 5.2 nm | 7.7 nm |
| SKUL-3 | 1.4 nm | 6.7 nm | 8.1 nm |
| SKUL-4 | 1.5 nm | 7.4 nm | 8.9 nm |

Scanning Electron Microscope (SEM) Analysis

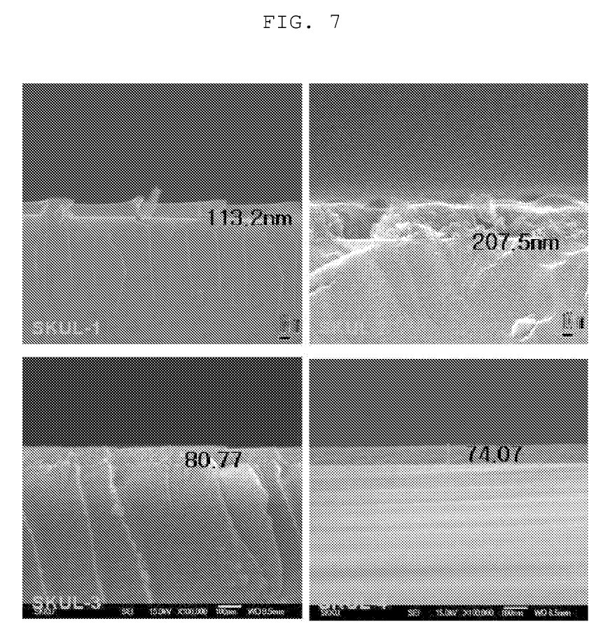

FIG. 7 illustrates results obtained by a field emission scanning electron microscope (FESEM; JEOL, 7000F). As illustrated in TABLE 3, the lamella structured thin films of the present invention have thicknesses of 74 to 207 nm.

TABLE 3
Comparison of physical properties of lamella
structured thin film (SKUL series)

| | | | | Dielectric |
|---|---|---|---|---|
| | | | | constant |
| Thin film | Thickness | Hardness | Modulus | (K) |
| SKUL-1 | 113.2 nm | 2.17 GPa | 25 GPa | 1.15 |
| SKUL-2 | 207.5 nm | 1.00 GPa | 16 GPa | 1.68 |
| SKUL-3 | 80.77 nm | 1.11 GPa | 16 GPa | 1.16 |
| SKUL-4 | 74.07 nm | 1.28 GPa | 23 GPa | 1.51 |

Nonointendation

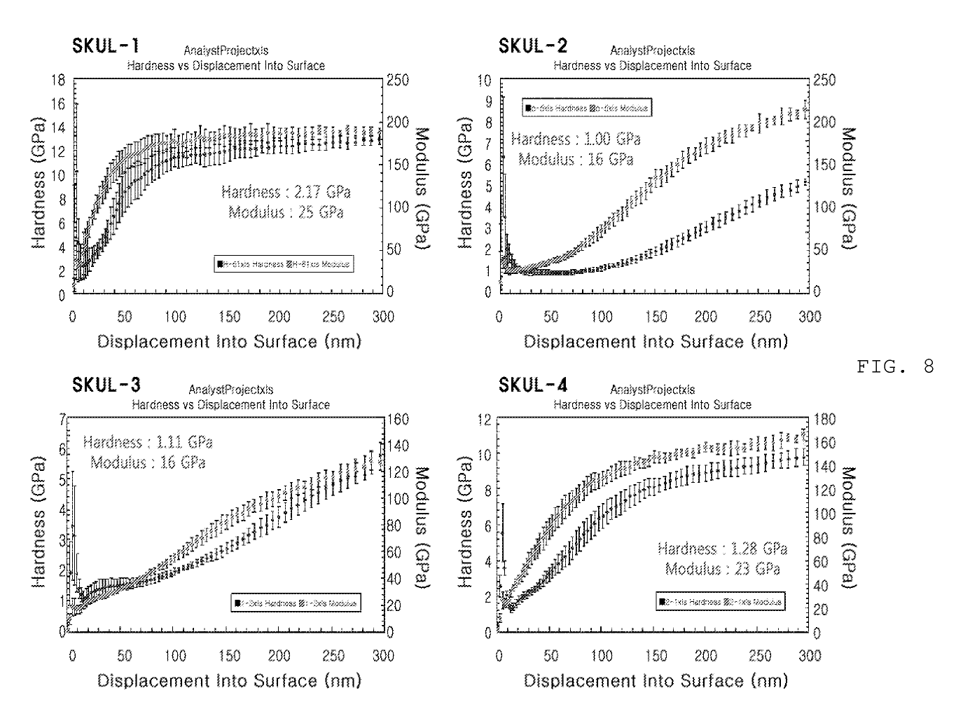

The nanoindentation measurement data of FIG. 8 illustrate the results of measuring the hardness and the modulus of the lamella structured thin film according to the present invention using a nanoindentator (manufactured by MTS). Considering that conventional low dielectric constant materials have hardness of no more than 0.5 GPa and modulus of no more than 3.0 GPa, it is noticed that the hardness and the modulus of the lamella structured thin films according to the present invention are significantly large (refer to TABLE 3).

Dielectric Constant

The dielectric constants of the thin films according to the present invention were measured by an HP 4248A Precision LCR meter and were calculated by the next equation;

Cₚ=ε₀εA/d

wherein, ε₀ represents the dielectric constant under vacuum, ε represents the dielectric constant of the thin film of the present invention, A represents the area of electrode, and d represents the thickness of the low dielectric material.

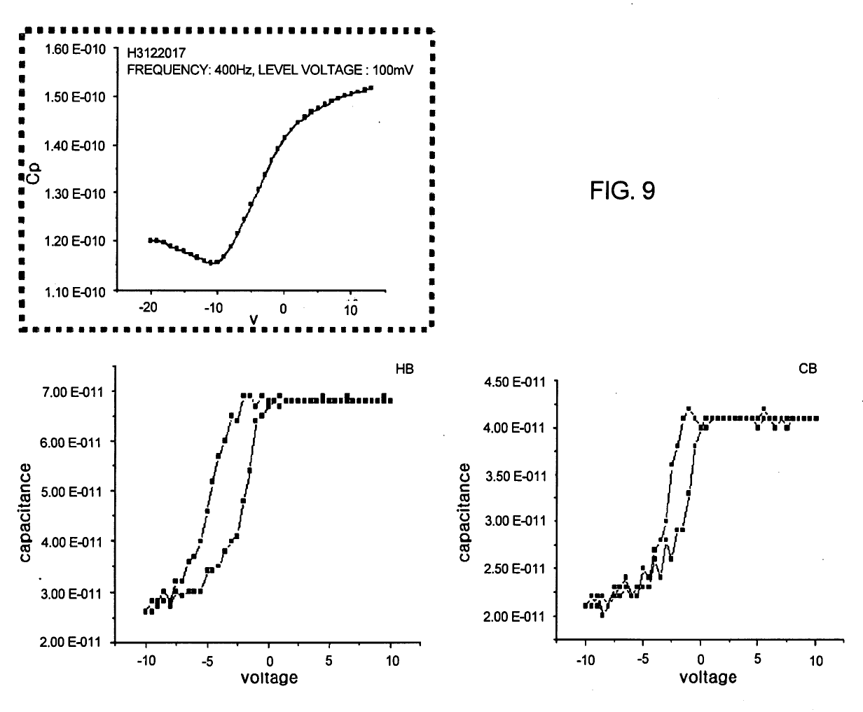

As illustrated in FIG. 9, considering that there are almost no materials having dielectric constants no more than 2.0 among conventional low dielectric constant materials, it is noticed that the dielectric constants of the lamella structured thin films according to the present invention are significantly low (refer to TABLE 3).

Test on the Resistance Against Water Vapor Treatment

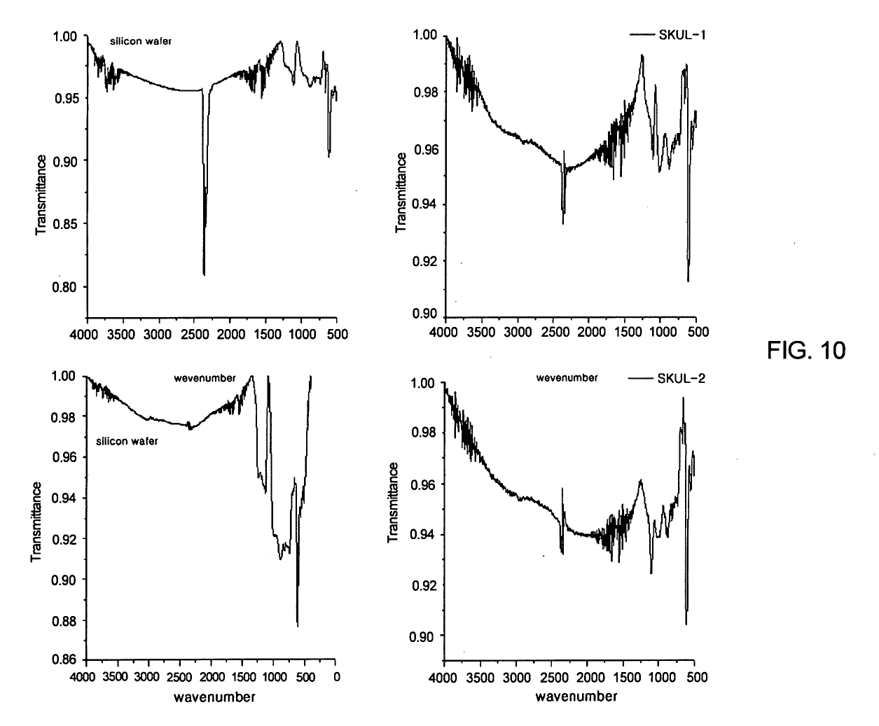

In order to test the moisture absorption property of the lamella structured thin films, the following analysis experiments were performed. After leaving the manufactured thin films in the vapor environment of boiling water at 100° C., that is, in a significantly humid environment, for 30 minutes, an IR analysis was performed. The graphs in the left-hand side of FIG. 10 illustrate results of performing the IR analyses on the experiment samples SKUL-1 and -2 before the exposure to water vapor. The graphs in the right-hand side of FIG. 10 illustrate results of performing the IR analyses on the experiment samples SKUL-1 and -2 after exposing to the water vapor. Referring to FIG. 10, the water peak was not observed in the IR data on the experiment samples SKUL-1 and -2. It was noticed that the films of the present invention did not absorb water in the significantly humid environment, that is, had significantly low moisture absorbing properties.

Analysis of ²⁹Si Magic Angle Spinning Nuclear Magnetic Resonance (MAS NMR) Spectrums

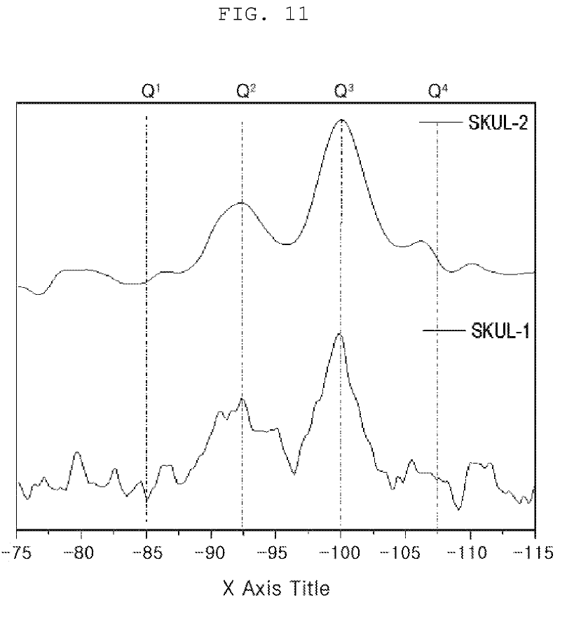

The NMR spectrums of the precursor silica sol solutions for the lamella structured thin films (SKUL series) were analyzed and the results were illustrated in FIG. 11. The structure and the size of mesostructure are related to the degree of the oligomerization reactions of the silica species. The features in these spectrums are characteristic for the silica sol solutions that produced the lamella structured thin films.

In order to compare the thin films of the present invention with the existing low dielectric constant materials, main results of reference documents are summarized.

### Comparative Embodiment 1

SiLK as low dielectric constant material was manufactured by a spin-coating method using a polymer and an organic solvent described in the reference document (Adv. Mater. 2000, 12, 1769). However, the dielectric constant of the material is 2.65, the Young's modulus of the material is 2.45 GPa, and the hardness of the material is 0.38 GPa. Therefore, it is noticed that the material of the comparative embodiment 1 has a significantly higher dielectric constant and significantly lower Young's modulus and hardness than those of the present invention. Therefore, it was noticed that the films of the present invention have significantly higher performance than conventional low dielectric constant materials.

### Comparative Embodiment 2

In accordance with the reference document (Chem. Mater. 2002, 14, 1845-1852), low dielectric constant thin film having mesopores was manufactured by a spin-coating method using a silica source based on hydrogen silsesquioxane and a solvent having low boiling point such as methylpropyl ketone.

### Comparative Embodiment 3

In accordance with the reference document (Langmuir 2001, 17, 6683-6691), low dielectric constant thin film was manufactured by a spin-coating method using PMSSQ/BTMSE prepolymer, Bis(1,2-trimethoxysilyl)ethane (BTMSE), and methyltrimethoxysilane (MSSQ).

As a result of measuring the dielectric constants of the thin films generated by the comparative embodiments 1 to 3, it was noticed that the dielectric constants were about 2.5 to 3.5, which are significantly larger than the dielectric constants of the films manufactured by the method of the present invention.

As described above, the lamella structured thin film according to the present invention has excellent mechanical strength and chemical stability, in particular, have significantly low dielectric constant of no more than 2.5 and high hardness. In addition, according to the method for manufacturing the lamella structured thin film of the present invention, the semiconductor manufacturing processes can be simple and economical since only pure silica is used and no additionally surface treatment is performed.

1. A lamella structured thin film, wherein silica layers and air layers are alternately and repeatedly stacked on the surface of a wafer in a vertical direction.

2. The lamella structured thin film as claimed in claim 1, wherein the silica layers having a thickness of 0.1 to 10 nm and the air layers having a thickness of 0.1 to 10 nm are stacked in a repeat thickness of 0.2 to 20 nm.

3. The lamella structured thin film as claimed in claim 2, wherein the silica layers having a thickness of 1 to 8 nm and the air layers having a thickness of 1 to 5 nm are stacked in a repeat thickness of 2 to 13 nm.

4. The lamella structured thin film as claimed in claim 1,
wherein the lamella structured thin film has a dielectric constant of 1.0 to 2.5 and a hardness of 0.2 to 3.0 GPa.

5. A method of manufacturing lamella structured thin films having ultralow dielectric constants and high hardness, comprising:
agitating silica sol solution comprising surfactant and silica precursor in order to induce the formation of self-assembly structures of silica and the surfactant;
spin-coating the solution on a silicon wafer;
aging the spun-cast thin film on the wafer; and
heat-treating the aged thin film to remove the surfactant and organic materials from the wafer.

6. The method as claimed in claim 5, wherein the silica sol solution comprises silica of 5 to 20 wt % and surfactant of 0.1 to 0.8 wt % for weight of the entire solution.

7. The method as claimed in claim 5, wherein the surfactant is selected from the group of surfactants that can form a mesoporous structure consisting of cetyltrimethylammonium bromide (CTAB), block copolymers having chemical formulas of EOₘPOₙEOₘ and EOₘPOₙ (EO is ethylene oxide, PO is propylene oxide, and n and m are integers), and block copolymer (in Brij type) having the chemical formula CₘH₂ₘ₊₁EOₙ (EO is ethylene oxide and n and m are integers).

8. The method as claimed in claim 6, wherein the surfactant is block copolymer (F-127) having the chemical formula of EO₁₀₆PO₇₀EO₁₀₆.

9. The method as claimed in claim 5, wherein agitating the silica sol solution is performed at a temperature of 20 to 30° C.

10. The method as claimed in claim 5, wherein agitating the silica sol solution is performed with a humidity of 18 to 40%.

11. The method as claimed in claim 5, wherein the spin coating is performed at a temperature of 25 to 35° C. and with a humidity of 55 to 80%.

12. The method as claimed in claim 5, wherein the aging is performed at 50 to 100° C. for 12 to 24 hours.

13. The method as claimed in claim 5, wherein the wafer is annealed at 300 to 800° C. for 2 to 6 hours.

14. The method as claimed in claim 5, wherein the silica precursor is selected from the group of silica precursors that can realize a mesoporous structure consisting of triethoxysilane (TES), trimethoxysilane (TMOS), vinyltrimethoxysilane (VTMOS), and tetraethoxysilane (TEOS).

15. The method as claimed in claim 5, wherein the silica sol solution further comprises organic solvent selected from the group consisting of water, butanol, methanol, ethanol, and propanol, acid catalyst selected from the group consisting of HNO₃, HCl, HBr, H₁, H₂SO₄, and HClO₄, or a combination of these.

16. The method as claimed in claim 5, wherein the lamella structured thin films have a dielectric constant of 1.0 to 2.5.

17. The method as claimed in claim 5, wherein the lamella structured thin films have a hardness of 0.2 to 3.0 GPa.

18. The method as claimed in claim 15,
wherein the organic solvent is ethanol and the acid catalyst is HCl.

19. The method as claimed in claim 15,
wherein the silica sol solution comprises TEOS as silica precursor, F-127 as surfactant, HCl as acid catalyst, and water and ethanol as solvents, and the molar concentration ratio of TEOS:F-127:HCl:H₂O:EtOH is 1:1.65×10⁻³ to 6.60×10⁻³:2.08×10⁻³ to 7.03×10⁻³:2.31 to 4.62:22.6 to 93.90.
